(19) United States
(12) Patent Application Publication
(10) Pub. No.: US 2014/0373918 A1
(43) Pub. Date: Dec. 25, 2014

(54) PHOTOVOL TAlC MODULES AND METHODS OF MAKING THE SAME

(71) Applicant: PPG Industries Ohio, Inc., Cleveland, OH (US)

(72) Inventors: Gereme Hensel, Pittsburgh, PA (US); Jiping Shao, Sewickley, PA (US); Edward R. Millero, JR., Gibsonia, PA (US); Irina G. Schwendeman, Wexford, PA (US)

(21) Appl. No.: 14/484,919

(22) Filed: Sep. 12, 2014

Related U.S. Application Data
(63) Continuation-in-part of application No. PCT/US2013/031239, filed on Mar. 14, 2013.
Application No. PCT/US2013/031239 is a continuation of application No. 13/420,081, filed on Mar. 14, 2012, now abandoned.

(51) Int. Cl. H01L 31/048; H01L 31/18

(52) U.S. Cl. CPC H01L 31/0481; H01L 31/1864
USPC 136/256; 438/66

(57) ABSTRACT

Photovoltaic modules and methods of making photovoltaic modules are disclosed. The photovoltaic modules comprise a front transparency, at least one photovoltaic cell, and a polyurea back coat.

### CROSS REFERENCE TO RELATED APPLICATIONS

This application is a Continuation-In-Part of International Patent Application No. PCT/US2013/031239 filed Mar. 14, 2013, which in turn claims priority to U.S. patent application Ser. No. 13/420,081, filed Mar. 14, 2012. Each of the referenced previously-filed applications is incorporated by reference herein in its entirety.

### TECHNICAL FIELD

The present disclosure relates to photovoltaic modules and, more particularly, coatings useful for coating or encapsulating photovoltaic modules, and methods for making the same.

### BACKGROUND

Photovoltaic modules produce electricity by converting electromagnetic energy into electrical energy. Photovoltaic modules use encapsulant materials to provide durability, weather resistance, and increased service life, particularly in outdoor operating environments.

There are many types of thin film photovoltaic modules that have been developed. While various materials and configurations exist among the thin film technology, most thin film photovoltaic modules comprise the following basic elements: a transparent front layer, which can be glass, transparent polymer, or transparent coating; a transparent, conductive top layer or grid that carries away current; a thin central sandwich of semiconductors that form a junction to separate charge; a back contact that can be a metal film; an encapsulant layer, and a backsheet that protects from the environment and that can provide support to the module if needed.

A bulk photovoltaic module comprises a front transparency, such as a glass sheet or a pre-formed transparent polymer sheet (for example, a polyimide sheet); an encapsulant such as ethylene vinyl acetate (EVA); photovoltaic cells comprising wafers of photovoltaic semiconducting material such as a crystalline silicon (c-Si); and a back sheet. Bulk photovoltaic modules are typically produced in a batch or semi-batch vacuum lamination process in which the module components are preassembled into a module preassembly. The preassembly process comprises depositing the encapsulant material onto the front transparency, positioning the photovoltaic cells and electrical interconnections onto the encapsulant material, depositing additional encapsulant material onto the photovoltaic cell assembly, and depositing the back sheet onto the back side encapsulant material to complete the module preassembly. The module preassembly is placed in a specialized vacuum lamination apparatus that uses a compliant diaphragm to compress the module assembly and cure the encapsulant material under reduced pressure and elevated temperature conditions to produce the laminated photovoltaic module. The process effectively laminates the photovoltaic cells between the front transparency and a back sheet with the intermediate encapsulant material securing the sealing the photovoltaic cells. A similar lamination process is often used to produce thin-film photovoltaic modules, wherein the encapsulant material and the back sheet are laminated to a front transparency comprising deposited photovoltaic thin-film layers.

The information described in this background section is not admitted to be prior art.

### SUMMARY

In various aspects, a photovoltaic module comprises a front transparency, at least one photovoltaic cell, and a back coat. The back coat comprises a cured polyurea resin formed from a coating composition.

In other various aspects a method for preparing a photovoltaic module comprises positioning at least one photovoltaic cell adjacent to a front transparency, depositing a back coat onto a back side of the photovoltaic cell opposite the front transparency, and curing the deposited back coat, wherein the back coat comprises a polyurea formed from a coating composition.

It is understood that the invention disclosed and described in this specification is not limited to the aspects summarized in this Summary.

### BRIEF DESCRIPTION OF THE DRAWINGS

Various features and characteristics of the non-limiting and non-exhaustive aspects disclosed and described in this specification can be better understood by reference to the accompanying figures, in which:

FIG. 1 is a schematic diagram illustrating a bulk photovoltaic module comprising a protective coating system;

FIG. 2 is a schematic diagram illustrating a thin film photovoltaic module comprising a protective coating system; and

FIG. 3 is a schematic diagram illustrating a method of preparing a photovoltaic module comprising a protective coating system.

The reader will appreciate the foregoing details, as well as others, upon considering the following detailed description of various non-limiting and non-exhaustive aspects according to this specification.

### DESCRIPTION

Various aspects described in this specification relate to protective coating systems that can provide one or more advantages to photovoltaic modules, such as good durability, moisture barrier, abrasion resistance, and the like.

In various aspects, a photovoltaic module is described. The photovoltaic module comprises a front transparency, at least one photovoltaic cell, and a back coat. The back coat comprises a cured polyurea resin formed from a coating composition comprising a polyisocyanate, a polyamine, a diamine chain extender and an amine-functional and/or hydroxy-functional siloxane. The coating composition comprises an aliphatic composition comprising a polyamine comprising a polyaspartic ester or a cyclo-aliphatic polyaspartic ester, a diamine chain extender comprising an aliphatic cyclic secondary amine, and an amine-functional siloxane. Physical and chemical advantages of the back coat can include robust application, impact protection, high durability and resistance to abrasion, and/or chemical and weather resistance.

Photovoltaic modules produce electricity by converting electromagnetic energy of the photovoltaic module into electrical energy. To survive in harsh operating environments, photovoltaic modules use encapsulant materials to provide durability and module life. “Encapsulant,” “encapsulated” and like terms refer to the covering of a component such as a photovoltaic cell with a layer or layers of material such that the surface of the component is not exposed and/or to protect the photovoltaic cell from the environment. The “backing layer,” “backsheet,” “back coat” or like terms as used herein refers to a layer that is located on the side of the photovoltaic cell opposite the front transparency.

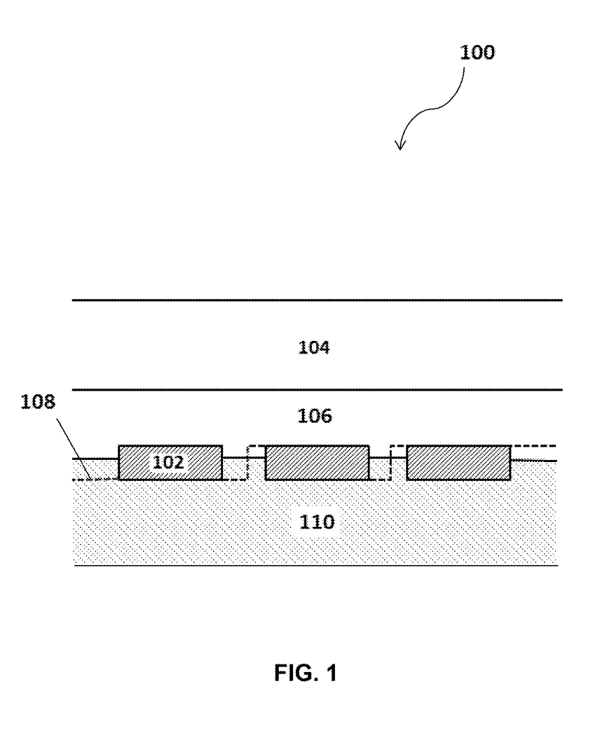

As schematically illustrated in FIG. 1, a photovoltaic module can include a bulk photovoltaic module 100 comprising a plurality of electrically interconnected photovoltaic cells 102 adhered to a front transparency 104. The photovoltaic cells 102 are positioned such that a front contact (not shown) of the photovoltaic cells 102 is facing the front transparency 104. The photovoltaic module 100 can further include an encapsulant layer 106 adjacent to the front transparency 104. The encapsulant layer 106 can provide adhesion of the photovoltaic cells 102 to the front transparency 104. The photovoltaic module 100 further comprises electrical interconnections 108 that link or connect the photovoltaic cells 102 applied to the encapsulant layer 106, and a back coat 110 deposited on at least a portion of the electrically interconnected photovoltaic cells 102 and/or encapsulant layer 106. In various aspects, the front transparency 104 comprises a planar sheet of transparent material comprising an outward-facing surface of a photovoltaic module. Any suitable transparent material can be used for the front transparency 104 including, but not limited to, glasses such as, for example, silicate glasses, and polymers such as, for example, polyimide, polycarbonate, and the like, or other planar sheet material that is transparent to electromagnetic radiation in a wavelength range that can be absorbed by a photovoltaic cell and used to generate electricity in a photovoltaic module. The term “transparent” refers to the property of a material in which at least a portion of incident electromagnetic radiation in the visible spectrum (i.e., approximately 350 to 750 nanometer wavelength) passes through the material with negligible attenuation.

In various aspects the photovoltaic module 100 further comprises the encapsulant layer 106 adjacent to the front transparency 104. The encapsulant layer 106 can be applied or deposited on at least a portion of the front transparency 104. As used herein “encapsulant layer” refers to a layer of polymeric materials used to adhere photovoltaic cells to front transparencies and/or back sheets in photovoltaic modules, and/or encapsulate photovoltaic cells within a covering of polymeric material. In various aspects, the encapsulant layer 106 comprises ethylene vinyl acetate (EVA). For example, the encapsulant layer 106 can be formed from a solid sheet of EVA. In other various aspects, the encapsulant layer 106 can comprise a cured clear fluid encapsulant deposited onto one side of the front transparency 104. As used herein, the term “clear” refers to samples exhibiting a transmittance exceeding 85% as evaluated under ASTM E 308-06 “Standard Practice for Computing the Colors of Objects by Using the Commission Internationale de l'Eclairage (CIE) System.” For example, in various aspects the term “clear” refers to samples of 8-10 mils thickness film deposited on Solarphire PV glass (3.2 mm glass) exhibiting a transmittance exceeding 85% evaluated using the ASTM E 308-06 standard (employing an X-Rite® Color i® 7 Spectrophotometer, commercially available from X-Rite, Inc., Grand Rapids, Mich., USA) using a CIE system Y value for D65 (incandescent) illumination and a 10° standard observer. As used herein to describe a fluid encapsulant the term “fluid” includes liquids, powders and/or other materials that are able to flow into or fill the shape of a space such as a front sheet.

Photovoltaic cells 102 and the electrical interconnections 108 can be positioned on the encapsulant layer 106 so that each photovoltaic cell 102 can be electrically connected to at least one other cell. Photovoltaic cells 102 include constructs comprising a semiconductor wafer positioned in between two electrically conducting contacts. In various aspects the semiconductor wafer can comprise a crystalline silicon wafer. The first electrically conducting contact can comprise a transparent conducting oxide film layer deposited onto one side of the crystalline silicon wafer or semiconductor wafer. The second electrically conducting contact can comprise a metallic layer deposited onto an opposite side of the crystalline silicon wafer or semiconductor wafer. In various aspects, photovoltaic cells 102 can comprise bulk photovoltaic cells (e.g., ITO- and aluminum-coated crystalline silicon wafers). In various aspects an assembly of the photovoltaic cells 102 and the electrical interconnections 108 can be used. The photovoltaic module 100 can comprise multiple bulk photovoltaic cells that each may comprise a crystalline silicon wafer. In other various aspects the photovoltaic cell can comprise multiple thin-film photovoltaic cells that each may comprise a plurality of deposited photovoltaic layers.

The photovoltaic module 100 can further comprise a protective coating or back coat 110. The back coat 110 may comprise multiple coating layers. The back coat 110 can be derived from any number of coatings, including powder coatings, liquid coatings and/or electrodeposited coatings. A durable, moisture resistant and/or abrasion resistant protective coating can be used as a backing or encapsulant layer to reduce or eliminate corrosion associated with photovoltaic cell failure.

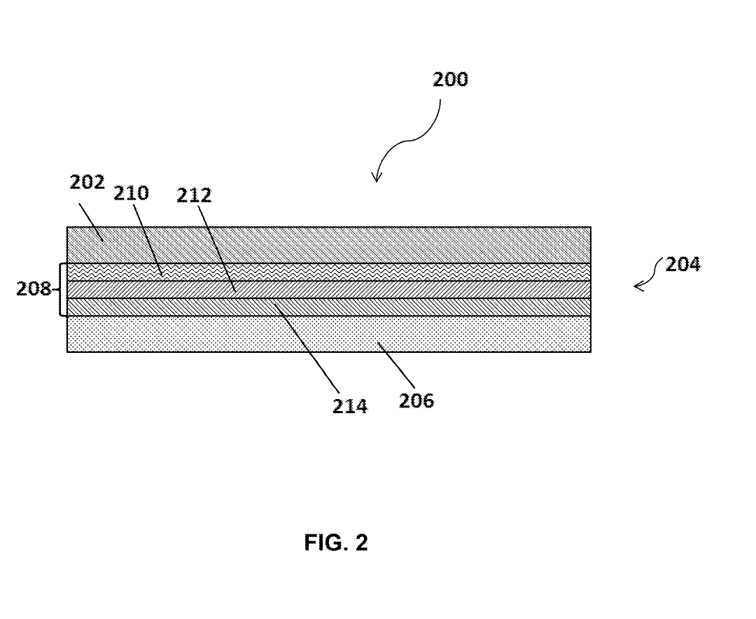

Although the photovoltaic module 100 is illustrated in FIG. 1 as a bulk film photovoltaic module, in various aspects, the photovoltaic module can comprise a thin film photovoltaic module. As shown in FIG. 2, a thin film photovoltaic module 200 can comprise a module including a front transparency 202, at least one photovoltaic cell 204, and a back coat 206.

The front transparency 202 can comprise a material that can be transparent to electromagnetic radiation in a wavelength range that can be absorbed by the photovoltaic cell 204 and used to generate electricity. The front transparency can comprise a planar sheet of transparent material comprising the outward-facing surface of a photovoltaic module 200. The front transparency 202 can comprise the same or similar materials and performs the same or similar functions as the front transparency 104 as described above in connection with the bulk photovoltaic module 100 shown in FIG. 1.

The thin film photovoltaic module 200 of FIG. 2 can be fabricated by deposition of multiple thin film photovoltaic cells 204 that each may comprise a plurality of deposited photovoltaic layers 208 onto the front transparency 202. In various aspects, the plurality of deposited photovoltaic layers 208 can include a transparent conducting oxide layer or other transparent conducting film 210. The transparent conducting film 210 can be optically transparent and/or electrically conductive providing a junction between the front transparency 202 and at least one semiconductor active material layer 212. The transparent conducting film 210 can act as a window for the passage of light through to the at least one semiconductor active material layer 212 beneath and/or can act as an ohmic contact for electron transport out of the photovoltaic module 200. The transparent conducting film 210 can be fabricated from materials that have greater than 80% transmittance of incident light as well as conductivities greater than 10³ S/cm for efficient electron/hole transport. For example, the transparent conducting film can include a transparent conducting oxide comprising at least one of indium tin oxide, fluorine doped tin oxide, doped zinc oxide, or combinations thereof. The transparent conducting film 210 can be deposited or grown onto the front transparency 202 using a variety of deposition techniques. For example, the transparent conducting film can be deposited using aerosol-assisted pyrolytic deposition, metal organic chemical vapor deposition (MOCVD), metal organic molecular beam deposition (MOMBD), spray pyrolysis, pulsed laser deposition (PLD), fabrication techniques involving magnetron sputtering of the film, or combinations thereof.

The transparent conducting film 210 can be in direct contact with the semiconductor active material layer 212. In various aspects, the semiconductor active material layer 212 comprises a layer of photovoltaic semiconducting material (e.g., amorphous silicon, cadmium telluride, copper indium diselenide, or combinations thereof) deposited onto the transparent conducting film 210. The semiconductor active material layer 212 may function to produce electrons available for conduction through the photovoltaic module 200.

The semiconductor active material layer 212 can be in direct contact with a metallic layer 214. The metallic layer 214 can comprise, for example, aluminum, nickel, molybdenum, copper, silver, gold, or combinations thereof. The metallic layer 214 can function as a back contact to the semiconductor active material layer 212 for conduction of electrical current throughout the photovoltaic module 200. The metallic layer 214 can be deposited onto the semiconductor active material layer 212 using a variety of deposition techniques. For example, the metallic layer 214 can be deposited onto the semiconductor active material layer 212 using screen printing, thermal spray coating, vapor deposition, chemical vapor deposition, or combinations thereof. The metallic layer 214 can be in direct contact with the back coat 206.

The back coat can comprise an aliphatic polyurea resin coating composition. In various aspects, the back coat can comprise a cured polyurea resin formed from a coating composition comprising components comprising a polyisocyanate, a polyamine, a diamine chain extender, and an amine-functional and/or hydroxy-functional siloxane, or combinations thereof. In various aspects the back coat comprises a spray applied and cured layer of polyurea resin formed from the coating composition. The back coat can function to protect the photovoltaic cells, the electrical interconnections, and/or the photovoltaic module from abrasion, erosion, and/or environmental damage, and may provide a moisture barrier, durability, and/or extended life to the photovoltaic module.

Referring back to FIG. 1, the back coat 110 can be deposited onto at least a portion of the photovoltaic module 100. In various aspects depositing the back coat 110 can comprise depositing a back coat 110 onto at least a portion of the photovoltaic cells 102 and the electrical interconnections 108. Depositing the back coat 110 can comprise depositing a back coat 110 onto the back side of the photovoltaic cell 102 opposite the front transparency 104. The back coat 110 can comprise a two-layer system comprising an underlying layer of cured liquid encapsulant (or an EVA sheet, etc.) and an overlying layer of cured polyurea back coat.

A problem with prior two- or more-component polyurea coating systems and compositions is that the combined liquid coating compositions can rapidly gel and cure, which can limit pot life. Aliphatic primary polyamines, for example, generally react rapidly with polyisocyanates, which can limit their commercial applications. However, efforts to decrease the crosslinking rate of the polyisocyanates and polyamines that form polyurea coatings, thereby increasing the pot life of the mixed coating composition, also tend to simultaneously increase the cure time of a coating film applied to a substrate.

Polyamines can confer advantageous properties to the back coat. For example, a polyamine component can reduce drying and/or curing times, provide for curing at ambient temperatures, and confer impact, abrasion, corrosion, chemical, and weather resistance. Polyamines can be formulated with slower reaction rates to accommodate batch-mixing and thinner film application. Further, polyamine coatings are generally UV and light stable and provide the beneficial properties of polyurea (rapid curing, robust application, and 100% solids) with controlled moisture vapor transmission rate (MVTR) permeance. Thus, the back coat can provide for rapid curing at ambient temperatures and control of gel time. For example, the back coat can provide a curing time of 5-60 seconds with a gel time of 5-120 seconds.

The polyamine component of the back coat can comprise a mixture of polyaspartic esters that can be cross-linked with polyisocyanates to provide a coating composition exhibiting a relatively long pot life and a relatively short cure time. The controlled reactivity of polyaspartic esters can result from the sterically hindered environment of the secondary amine groups, which are located in a beta position relative to an ester carbonyl, and due to potential hydrogen bonding between the secondary amine groups and the ester carbonyl. Polyaspartic esters can be prepared by the Michael addition reaction of polyamines with dialkyl maleate.

The back coat can comprise a cured polyurea resin formed from a coating composition comprising a polyisocyanate and a polyamine having the structure of formula (I):

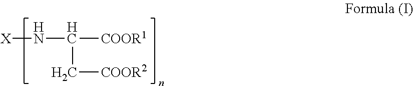

wherein:

n is an integer of 2 to 4

X represents an aliphatic residue;

R¹ and R² represent organic groups that are inert to isocyanate groups under reaction conditions and that can be the same or different organic groups; and

n is at least 2.

In formula (I), the aliphatic residue X can correspond to a straight or branched alkyl and/or cycloalkyl residue of an n-valent polyamine that can be reacted with a dialkylmaleate in a Michael addition reaction to produce a polyaspartic ester. For example, the residue X can correspond to an aliphatic residue from an n-valent polyamine including, but not limited to, ethylene diamine; 1,2-diaminopropane; 1,4-diaminobutane; 1,6-diaminohexane; 2,5-diamino-2,5-dimethylhexane; 2,2,4- and/or 2,4,4-trimethyl-1,6-diaminohexane; 1,11-diaminoundecane; 1,12-diaminododecane; 1-amino-3,3,5-trimethyl-5-amino-methylcyclohexane; 2,4′- and/or 4,4′-diaminodicyclohexylmethane; 3,3′-dimethyl-4,4′-diaminodicyclohexylmethane; 2,4,4′-triamino-5-methyldicyclohexylmethane; polyether-polyamines with aliphatically bound primary amino groups and having a number average molecular weight of 148 to 6000 g/mol; isomers of any thereof, and combinations thereof.

In various aspects, the residue X can be obtained from 1,4-diaminobutane; 1,6-diaminohexane; 2,2,4- and/or 2,4,4-trimethyl-1,6-diaminohexane; 1-amino-3,3,5-trimethyl-5-aminomethylcyclohexane; 4,4′-diaminodicyclohexylmethane; 3,3′-dimethyl-4,4′-diaminodicyclohexylmethane; 1,5-diamine-2-methyl-pentane; and combinations thereof.

The phrase “inert to isocyanate groups under reaction conditions,” which is used to define groups R¹ and R² in formula (I), means that these groups do not have Zerevitinov-active hydrogens. Zerevitinov-active hydrogen is defined in Rompp's Chemical Dictionary (Rommp Chemie Lexikon), 10th ed., Georg Thieme Verlag Stuttgart, 1996, which is incorporated by reference into this specification. Generally, groups with Zerevitinov-active hydrogen are understood in the art to mean hydroxyl (OH), amino (NHx), and thiol (SH) groups. In various aspects, R¹ and R², independently of one another, can be C₁ to C₁₀ alkyl residues, such as, for example, methyl, ethyl, or butyl residues.

The polyamine component can comprise a reaction product of two equivalents of diethyl maleate with one equivalent of 1,5-diamine-2-methyl-pentane; 4,4′-diaminodicyclohexylmethane; or 3,3′-dimethyl-4,4′-diaminodicyclohexylmethane. These reaction products can have the molecular structures shown in formulas (II)-(IV), respectively:

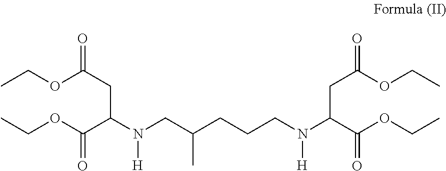 [SMILES: CCOC(=O)CC(NCCCC(C)CNC(CC(=O)OCC)C(=O)OCC)C(=O)OCC]

In various aspects, the polyamine comprises a cyclo-aliphatic polyaspartic ester. For example, the polyamine can comprise a polyamine having the structure of formula (III) or formula (IV).

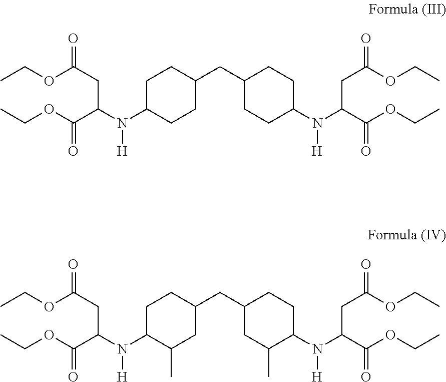

The polyamine component can comprise a mixture of any two or more polyaspartic esters, and in some aspects, a mixture of any two of the polyaspartic esters shown in formulas (II)-(IV). The polyamine component can also comprise a mixture of the three polyaspartic esters shown in formulas (II)-(IV).

Examples of other suitable polyamines that can be used as a component alone or in combination with each other, and/or in combination with any of the polyaspartic esters described above, include the polyaspartic esters described in U.S. Pat. Nos. 5,126,170; 5,236,741; 5,489,704; 5,243,012; 5,736,604; 6,458,293; 6,833,424; 7,169,876; and in U.S. Patent Publication No. 2006/0247371, which are incorporated by reference into this specification. In addition, suitable polyamines are commercially available from Bayer MaterialScience LLC, Pittsburgh, Pa., USA, under the trade names DESMOPHEN® NH 1220, DESMOPHEN® NH 1420, DESMOPHEN® NH 1520, and DESMOPHEN® NH 1521.

The polyaspartic ester component of the back coat 110 can be cross-linked with a polyisocyanate. As used herein, the term “polyisocyanate” refers to compounds comprising at least two un-reacted isocyanate groups. Polyisocyanates include diisocyanates and diisocyanate reaction products comprising, for example, biuret, isocyanurate, uretdione, urethane, urea, iminooxadiazine dione, oxadiazine trione, carbodiimide, acyl urea, allophanate groups, and combinations thereof. As used herein, the term “polyamine” refers to compounds comprising at least two free primary and/or secondary amine groups. Polyamines include polymers comprising at least two pendant and/or terminal amine groups.

The polyisocyanate component can include any of the known polyisocyanates of polyurethane chemistry. Examples of suitable lower molecular weight polyisocyanates (e.g., having a molecular weight of 168 to 300 g/mol) include, but are not limited to, 1,4-tetra-methylene diisocyanate; methylpentamethylene diisocyanate; 1,6-hexamethylene diisocyanate (HDI); 2,2,4-trimethyl-1,6-hexamethylene diisocyanate; 1,12-dodecamethylene diisocyanate; cyclohexane-1,3- and -1,4-diisocyanate; 1-isocyanato-2-isocyanatomethyl cyclopentane; 1-isocyanato-3-isocyanatomethyl-3,5,5-trimethyl-cyclohexane (isophorone diisocyanate or IPDI); bis-(4-isocyanato-cyclohexyl)-methane; 1,3- and 1,4-bis-(isocyanatomethyl)-cyclohexane; bis-(4-isocyanatocyclo-hexyl)-methane; 2,4′-diisocyanato-dicyclohexyl methane; bis-(4-isocyanato-3-methyl-cyclohexyl)-methane; α,α,α′,α′-tetramethyl-1,3- and/or -1,4-xylylene diisocyanate; 1-isocyanato-1-methyl-4(3)-isocyanatomethyl cyclohexane; 2,4- and/or 2,6-hexahydro-toluylene diisocyanate; 1,3- and/or 1,4-phenylene diisocyanate; 2,4- and/or 2,6-toluene diisocyanate; 2,4- and/or 4,4′-diphenylmethane diisocyanate (MDI); 1,5-diisocyanato naphthalene; and combinations thereof.

The polyisocyanate component can comprise an aliphatic diisocyanate, an aliphatic diisocyanate adduct, an aliphatic diisocyanate prepolymer, or combinations thereof. Suitable aliphatic diisocyanates include, for example, hexamethylene diisocyanate (HDI); isophorone diisocyanate (IPDI); 2,4′- and/or 4,4′-diisocyanato-dicyclohexyl methane; adducts thereof; and prepolymers comprising residues thereof.

Additional suitable polyisocyanate components include derivatives of the above-mentioned monomeric diisocyanates. Suitable diisocyanate derivatives include, but are not limited to, polyisocyanates containing biuret groups as described, for example, in U.S. Pat. Nos. 3,124,605 and 3,201,372, which are incorporated by reference into this specification. Suitable diisocyanate derivatives also include, but are not limited to, polyisocyanates containing isocyanurate groups (symmetric trimers) as described, for example, in U.S. Pat. No. 3,001,973, which is incorporated by reference into this specification. Suitable diisocyanate derivatives also include, but are not limited to, polyisocyanates containing urethane groups as described, for example, in U.S. Pat. Nos. 3,394,164 and 3,644,457, which are incorporated by reference into this specification. Suitable diisocyanate derivatives also include, but are not limited to, polyisocyanates containing carbodiimide groups as described, for example, in U.S. Pat. No. 3,152,162, which is incorporated by reference into this specification. Suitable diisocyanate derivatives also include, but are not limited to, polyisocyanates containing allophanate groups. Suitable polyisocyanates also include, but are not limited to, polyisocyanates containing uretdione groups.

In various aspects, suitable polyisocyanate components comprise an asymmetric diisocyanate trimer (iminooxadiazine dione ring structure) such as, for example, the asymmetric diisocyanate trimers described in U.S. Pat. No. 5,717,091, which is incorporated by reference into this specification. In various aspects, the polyisocyanate component can comprise an asymmetric diisocyanate trimer based on hexamethylene diisocyanate (HDI); isophorone diisocyanate (IPDI); or combinations thereof.

Isocyanate group-containing prepolymers and oligomers based on polyisocyanates can also be used as the polyisocyanate component. Polyisocyanate-functional prepolymers and oligomers can have an isocyanate content ranging from 0.5% to 30% by weight, and in some aspects, 1% to 20% by weight, and can be prepared by the reaction of starting materials, such as, for example, isocyanate-reactive compounds such as polyols, at an NCO/OH equivalent number ratio of 1.05:1 to 10:1, and in some aspects, 1.1:1 to 3:1.

Examples of other suitable polyisocyanates that can be used as the polyisocyanate component alone or in combination with each other, and/or in combination with any of the polyisocyanates described above, include the polyisocyanates described in U.S. Pat. Nos. 5,126,170; 5,236,741; 5,489,704; 5,243,012; 5,736,604; 6,458,293; 6,833,424; 7,169,876; and in U.S. Patent Publication No. 2006/0247371, which are incorporated by reference into this specification.

The phrase “diamine chain extender” used herein means low molecular weight diamine compounds that assist in polymeric extension of the molecules within a back coat. The diamine chain extender can include an aliphatic secondary diamine, and/or an aliphatic secondary diamine and other components including a cycloaliphatic primary diamine, aliphatic secondary diamines, a noncyclic diamine, an aliphatic secondary diamine and an aliphatic primary diamine, an aliphatic diimine, and combinations thereof. In various aspects an aliphatic secondary diamine can include alkyl secondary diamines where the alkyl portion of the diamine can be aliphatic, where “alkyl portion” refers to a moiety to which the amino groups are bound. The alkyl portion of the aliphatic diamine can be cyclic, branched, or, straight chain. The amino alkyl groups of the aliphatic secondary diamine can be cyclic, branched, or straight chain. For example, the amino alkyl groups can include straight chain or branched chain alkyl groups having from three to twelve carbon atoms. Further examples of suitable amino alkyl groups can include ethyl, propyl isopropyl, n-butyl, sec-butyl, t-butyl, pentyl, cyclopentyl, hexyl, methylcyclohexyl, heptyl, octyl, cyclooctyl, nonyl, decyl, dodecyl, and the like, or combinations thereof. In various aspects, the aliphatic secondary diamine can include eight to forty carbon atoms. In various aspects, the aliphatic secondary diamine can include ten to thirty carbon atoms.

Aliphatic secondary diamines can include, but are not limited to, N,N′-diisopropylethylenediamine, N,N′-di-sec-butyl-1,2-diaminopropane, N,N′-di(2-butenyl)-1,3-diaminopropane, N,N′-di(1-cyclopropylethyl)-1,5-diaminopentane, N,N′-di(3,3-dimethyl-2-butyl)-1,5-diamino-2-methylpentane, N,N′-di-sec-butyl-1,6-diaminohexane, N,N′-di(3-pentyl)-2,5-dimethyl-2,5-hexanediamine, N,N′-di(4-hexyl)-1,2-diaminocyclohexane, N,N′-dicyclohexyl-1,3-diaminocyclohexane, N,N′-di(1-cyclobutylethyl)-1,4-diaminocyclohexane, N,N′-di(2,4-dimethyl-3-pentyl)-1,3-cyclohexanebis(methylamine), N,N′-di(1-penten-3-yl)-1,4-cyclohexanebis(methylamine), N,N′-diisopropyl-1,7-diaminoheptane, N,N′-di-sec-butyl-1,8-diaminooctane, N,N′-di(2-pentyl)-1,10-diaminodecane, N,N′-di(3-hexyl)-1,12-diaminododecane, N,N′-di(3-methyl-2-cyclohexenyl)-1,2-diaminopropane, N,N′-di(2,5-dimethylcyclopentyl)-1,4-diaminobutane, N,N′-di(isophoryl)-1,5-diaminopentane, N,N′-di(methyl)-2,5-dimethyl-2,5-hexanediamine, N,N′-di(undecyl)-1,2-diaminocyclohexane. N,N′-di-2-(4-methylpentyl)-isophoronediamine, and N,N′-di(5-nonyl)-isophoronediamine. A suitable aliphatic secondary diamine can be N,N′-di-(3,3-dimethyl-2-butyl)-1,6-diaminohexane. In addition, suitable diamine chain extenders are commercially available from the Hanson Group, LLC, Alpharetta, Ga., USA, under the trade name HXA CE-425, the Huntsman Corporation, The Woodlands, Tex., USA under the trade name JEFFLINK® 754 diamine, and Tri-iso, Cardiff by the Sea, Calif., USA under the trade name CLEARLINK® 1000.

The diamine chain extender can contribute to high tensile strength, elongation and tear resistance values of the back coat. Diamine chain extenders and cross-linkers can be used in the composition of the back coat to control the gel time of the polymerization reaction and provide increased control of the physical properties of the nascent polymer such as the cure rate, adhesion, flow and level, and polymer hardness. Further, diamine chain extenders can provide increased tensile strength and hardness to polyurea formulations.

In various aspects, the back coat comprises a cured polyurea resin formed from a coating composition comprising a polyisocyanate, a polyamine having the structure of formula (I), a diamine chain extender having the structure:

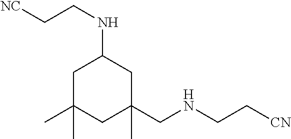 [SMILES: CC1(C)CC(NCCC#N)CC(C)(CNCCC#N)C1]

and an amine-functional siloxane and/or hydroxy functional siloxane.

An amine-functional and/or hydroxy-functional siloxane can be used to improve the physical properties and long-term performance of the back coat. The phrase “amine-functional siloxane” refers to amine-functional polysiloxane oligomers or polymers having primary and/or secondary amine groups. For example, an amine-functional polysiloxane can be represented by the following formula (V):

R₃SiO[R₂SiO]ₓ[RQ¹SiO]_{y}[RQSiO]₂SiR₃ Formula V

Where: R denotes an alkyl group of one to four carbons, OH, an alkoxy group or a phenyl group with the proviso that at least fifty percent of the total R groups are methyl; Q denotes an amine functional substituent of the formula —R²Z, wherein R² can be a divalent alkylene radical of three to six carbon atoms or a radical of the formula —CH₂CH₂CH₂OCH₂—CHOHCH₂— and Z can be a monovalent radical which can be selected from the group consisting of radicals including —NR₂³, —NR³(CH₂)ₙNR₂³, and

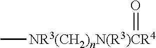

wherein R³ denotes hydrogen or an alkyl group of one to four carbons, R⁴ denotes an alkyl group of one to four carbons and n is a positive integer from two to six; x, y, and z are integers the sum of which can be within the range of twenty-five to eight hundred; and Q¹ denotes an amine functional substituent as defined above which additionally includes a carbon bonded silicon atom having a silicon-bonded hydrolyzable group. This can be represented by:

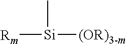

in which m can be an integer having a value of zero, one or two. R for purposes of this radical denotes an alkyl group of one to four carbons and y can be at least one.

One amine functional siloxane polymer corresponding to Formula (V) can be Formula VI:

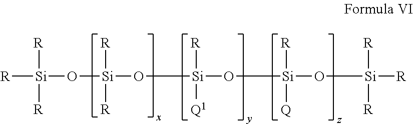

in which Q is —CH₂CHCH₃CH₂NHCH₂CH₂NH₂; and
wherein Q¹ is —CH₂CHCH₃CH₂NHCH₂CH₂NHCH₂CH₂CH₂Si(OCH₃)₃; and the sum of the integers x, y and z is two hundred.

Useful R groups can include methyl, ethyl, propyl, isopropyl, butyl, isobutyl, phenyl, or combinations thereof, with the proviso that at least fifty percent of the R groups are methyl. The R groups can all be the same or different.

In the formula for the amine functional substituent Q represented by —R²Z, the alkylene radicals denoted by R² can include trimethylene, tetramethylene, pentamethylene, —CH₂CHCH₃CH₂— and —CH₂CH₂CHCH₃CH₂—. Siloxane polymers wherein the R² radical denotes —CH₂CH₂CH₂OCH₂CHOHCH₂— can also be employed. In varied aspects siloxanes wherein R² can be trimethylene or an alkyl substituted trimethylene radical such as —CH₂CHCH₃CH₂— can also be used.

Z represents an amine radical that can be substituted or unsubstituted. Amine radicals that may be employed as noted previously include —NR₂³, —NR³(CH₂)ₙNR₂³, and

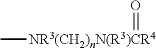

wherein R³ denotes hydrogen or an alkyl group of one to four carbons, R⁴ denotes an alkyl group of one to four carbons and n can be a positive integer from two to six. Alkyl groups of one to four carbon atoms represented by R³ and R⁴ include methyl, ethyl, propyl, butyl, isopropyl or isobutyl. Useful Z radicals include unsubstituted amine radicals such as —NH₂; alkyl substituted amine radicals such as —NHCH₃, —NHCH₂CH₂CH₂CH₃ and —N(CH₂CH₃)₂; aminoalkyl substituted amine radicals such as —NHCH₂CH₂NH₂, —NH(CH₂)₆NH₂ and —NHCH₂CH₂CH₂N(CH₃)₂; and aminoalkyl substituted amine radicals such as

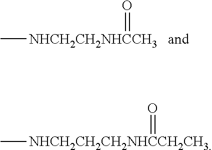

Siloxane polymers which are useful can vary in viscosity and polymerization. For example in the formula: R₃SiO[R₂SiO]x [RQ¹SiO]y [RQSiO]z SiR₃, the integers x, y and z have a sum within the range of twenty-five to eight hundred. However in various aspects siloxane polymers can possess values of x, y and z within the range of fifty to four hundred.

In various aspects the siloxane polymer comprises an amine-functional and/or a hydroxy-functional siloxane. As used herein, the term “hydroxy-functional siloxane” refers to polysiloxane oligomers having hydroxyl groups. For example, a hydroxy-functional siloxane can have a structure as shown in formula (VII):

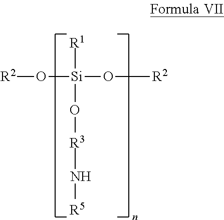

wherein each R¹ can be independently selected from the group comprising alkyl and aryl, each R² can be independently selected from the group comprising hydrogen, alkyl and aryl radicals, n can be selected so that the molecular weight for the functional polysiloxane can be in the range of from 400 to 10,000 g/mole and R³ can be a bivalent radical or —O—R³—NH—R⁵ can be hydroxy or alkoxy, and R⁵ can be selected from the group comprising hydrogen, or aminoalkyl, aminoalkenyl, aminoaryl, aminocycloalkyl radical, optionally substituted by alkyl, aryl, cycloalkyl, halogen, hydroxy, alkoxy, thioalkyl, amino, amino derivatives, amido, amidoxy, nitro, cyano, keto, acyl derivatives, acyloxy derivatives, carboxy, ester, ether, esteroxy, heterocycle, alkenyl or alkynyl and wherein 0 to 90% of —O—R³—NH—R⁵ can be hydroxy or alkoxy.

In various aspects, the hydroxy-functional siloxane component of the back coat can include hydroxyl groups bound to the silicon via Si—C bonds. For example, the hydroxy-functional siloxane can comprise difunctional, hydroxyl-terminated polysiloxane oligomers:

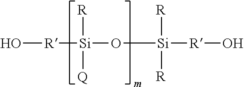

wherein R can be alkyl or aryl, R′ can be alky or aryl and m can be controlled. In various aspects, R′ can be such that the terminal groups are primary hydroxyl groups.

Suitable amine-functional siloxanes and/or hydroxy-functional siloxanes are commercially available from Evonik Industries, TEGO Products, Hopewell, Va., USA under the trade name TEGO PROTECT® 5000, (a solvent-free, hydroxy-functional polydimethyl siloxane).

In various aspects an additive including a polyether-polyamine, an ultraviolet stabilizer, pigments such as titanium dioxide (TiO₂), or combinations thereof can be included in the back coat. For example, a polyether-polyamine can impart flexibility and toughness to the back coat, a UV stabilizer can provide protection from ultraviolet radiation, and pigments such as titanium dioxide can impart color to the back coat or provide further control over moisture vapor transmission rate or other coating properties.

The composition of the back coat can comprise a polyether-polyamine. The phrase “polyether-polyamine,” “polymeric etheramine,” or “polyetheramine” as used herein means a compound comprising more than one ether group and including two or more primary amino groups. Polyether-polyamines generally have polyoxypropylene backbones and can be employed as both a soft-block and a chain extender portion of the coating system. The polyether-polyamine compound can be used as an additive to the back coat to impart lower viscosity to the curing agent system and to increase flexibility and toughness of the back coat.

Polyether-polyamines used in the coating composition of the back coat comprise the following empirical formula:

H[NHC₂H₃R(OC₂H₃R)ₓOC₂H₃R]_{y}NH₂

wherein R can be H, CH₃ and, depending on the method of preparation of the starting glycol, both H and CH₃ (such as when the product is derived from propylene oxide-capped polyethylene glycol), x can be an integer from 0 to 70 and y can be an integer from 1 to 20. In various aspects, x can be an integer from 1 to 30, from 1 to 15 or from 1 to 2 and y can be an integer from 1 to 10 or from 1 to 2.

It should be understood that the above formula is presented for the sake of convenience. In those cases where R═CH₃, it is contemplated that the position of the R group in the formula is not fixed but can be on either of the neighboring carbon atoms depending on the type of starting glycol or oxide and on the nature of the reaction conditions utilized in preparing the polyether-polyamine.

The polyether-polyamine can include a mixture of amine terminated ethylene oxide and/or propylene oxide polyether with molecular weights varying from 200 to 5000 g/mole. For example the polyether-polyamine can exhibit a molecular weight that can be 5000 g/mole, 3000 g/mole, 2000 g/mole, 400 g/mole, 200 g/mole, or a mixture of combinations thereof. In various aspects the polyether-polyamine can include 25 to 75 mole % ethylene oxide units and greater than 90% primary amine end groups. The polyetheramine can be an α,ω-diamino poly(oxyethylene-co-oxytetramethylene ether) random copolymer composition having 25 to 75 mole % oxyethylene units. The polyether-polyamine can comprise a polyether-triamine. Suitable polyether-polyamines are commercially available from the Huntsman Corporation, The Woodlands, Tex., USA under the trade name JEFFAMINE® T-3000, (a polyetheramine) and JEFFAMINE® T-5000 (a polyetheramine).

An ultraviolet (UV) stabilizer or absorber can be included in the back coat. In various aspects, molecules that function as ultraviolet light absorbers can include 2-(2-hydroxyphenyl)-benzotriazole compounds. Other classes of ultraviolet light absorbers can include 2-hydroxybenzophenones and diphenylcyanoacrylates.

In addition to absorbing ultraviolet light, the UV stabilizer can be transparent to visible light. Useful classes of amide-functional ultraviolet light absorbing compounds include amide containing 2-hydroxyphenylbenzotriazoles, 2-hydroxybenzophenones, diphenylcyanoacrylates, triazines, or combinations thereof.

Suitable 2-hydroxyphenylbenzotriazole compounds include those having the formula:

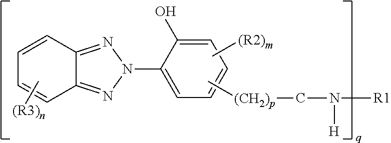

wherein R1 can be straight-chain or branched C1-C18 alkyl, straight-chain or branched C3-C18 alkyl which can be interrupted by O, S, or —NR4-, C5-C12 cycloalkyl, C6-C14 aryl, C7-C15 aralkyl, straight-chain or branched C3-C8 alkenyl, C1-C3 hydroxyalkyl or

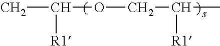

wherein R1′ can be H or straight-chain or branched C1-6 alkyl; R4 can be H, straight-chain or branched C1-C18alkyl, C6-C12 cycloalkyl, straight-chain or branched C3-C8 alkenyl, C6-C14 aryl or C7-C18 aralkyl; each R2 can be independently halogen, hydroxy, straight-chain or branched C1-6 alkyl, straight-chain or branched C1-6 alkoxy, straight-chain or branched C1-6 alkanol, amino, straight-chain or branched C1-6 alkylamino, or straight-chain or branched C1-6 dialkylamino; each R3 can be independently halogen, hydroxy, straight-chain or branched C1-6 alkyl, straight-chain or branched C1-6 alkoxy, straight-chain or branched C1-6 alkanol, amino, straight-chain or branched C1-6 alkylamino, straight-chain or branched C1-6 dialkylamino, or aliphatic or aromatic substituted sulfoxide or sulfone; m can be an integer from 0 to 3; n can be an integer from 0 to 4; p can be an integer from 1 to 6; q can be 1 or 2; and s can be an integer from 2 to 10.

Other ultraviolet light absorbing compounds can also be used, provided they contain an amide group. Examples of such compounds include p-hydroxybenzoates, triazines and diphenylcyanoacrylates. Amide functional ultraviolet light absorbing compounds can be used alone or in combination in the coatings of various aspects.

Synthetic polymers can be attacked by ultraviolet radiation causing these materials to crack or disintegrate upon prolonged exposure to sunlight. The UV stabilizer compound can be used as an additive that can provide crack resistance to the back coat. Moreover, the UV stabilizer can protect the back coat from the long-term degradation effects from ultraviolet radiation.

In various aspects, coats comprising the back coat can be applied or deposited onto all or a portion of the back side of the photovoltaic module, the photovoltaic cells, and the electrical interconnections, and cured to form a coat or layer thereon (e.g., topcoat, primer coat, tie coat, clear coat, or the like) using any suitable coating application technique. For example, the coatings of the present disclosure can be applied by spraying, dipping, rolling, brushing, roller coating, curtain coating, flow coating, slot die coating, and the like.

The coating can be deposited directly upon the back side of the photovoltaic module or other coatings can be applied there between. A layer of coating can be formed when a coating that is deposited onto a photovoltaic module or other coatings is cured or dried. In addition, in various aspects wherein an encapsulant layer comprises a liquid encapsulant applied to one side of a front transparency, the liquid encapsulant can be applied using any of the above-described coating application techniques.

The back coat can exhibit a Young's modulus in a range of 10 MPa to 900 MPa, or any sub-range subsumed therein, such as, for example, 10 to 800 MPa, or 50 to 700 MPa.

The back coat can reach elongation in the range of 10% to 300%, or any sub-range subsumed therein, such as, for example, 10% to 50%, 15% to 25%, or 18% to 24%.

The back coat can exhibit a tensile strength in a range of 10 MPa to 900 MPa, or any sub-range subsumed therein, such as, for example, 5 MPa to 100 MPa, 100 MPa to 500 MPa, 10 MPa to 200 MPa or 50 MPa to 100 MPa.

The back coat can exhibit a dry film thickness in the range of 0.5 to 50 mils, or any sub-range subsumed therein, such as, for example, 5 to 40 mils, 10 to 25 mils, 10 to 20 mils, or 10 to 15 mils.

The back coat can exhibit a moisture vapor transition rate permeance in the range of 1 to 1000 g*mil/m²*day, or any sub-range subsumed therein, such as, for example, 100 to 500 g*mil/m²*day, 50 to 400 g*mil/m²*day, 5 to 50 g/m²/day, or 20 to 40 g*mil/m²*day.

The back coat can exhibit a maximum permeance value ranging from 1 to 1,000 g*mil/m²*day, or any sub-range subsumed therein, such as, for example, 1 to 500 g*mil/m²*day.

The back coat can exhibit a dry insulation resistance of greater than 400 MΩ, or, in some aspects, greater than 500 MΩ, greater than 1000 MΩ, greater than 1500 MΩ, or greater than 2000 MΩ. In various aspects the above dry insulation resistance properties can be exhibited by a back coat having a dry film thickness less than 30 mils or, in some aspects, less than 25 mils, or less than 20 mils. For example, a less than 30 mils, less than 25 mils, or less than 20 mils thick back coat can exhibit a dry insulation resistance greater than 500 MΩ, greater than 1000 MΩ, greater than 1500 MΩ, or greater than 2000 MΩ.

The back coat can include a topcoat that comprises a dry (cured) film thickness ranging from 02 mils to 25 mils, or any sub-range subsumed therein, such as, for example, 1 mils to 10 mils, or 5 mils to 8 mils. In various aspects the back coat can comprise a two- or more-layer system comprising an underlying layer of cured liquid encapsulant and one- or more-overlying layers. The underlying layer(s) in between a topcoat, photovoltaic cells, and electrical interconnects can have a dry (cured) film thickness ranging from 0.2 mils to 10 mils, or any sub-range subsumed therein, such as, for example, 1 mils to 2 mils. A two- or more-layer back coat system comprising at least a topcoat and an underlying layer can together have a dry (cured) film thickness ranging from 0.5 mils to 50 mils, or any sub-range subsumed therein, such as, for example, 1 mils to 10 mils, or 5 mils to 8 mils.

It is contemplated that the coating methods described herein can employ coating compositions that are applied over all or at least a portion of a substrate and cured to form a coat or layer thereon (e.g., topcoat, primer coat, tie coat, clearcoat, or the like). The applied coats can then form a coating system over all or at least a portion of a substrate and cured which, individually, as a single coat, or collectively, as more than one coat, comprise a protective barrier over at least a portion of the substrate. One such coat can be formed from a fluid encapsulant which cures to form a transparent partial or solid coat on at least a portion of a substrate (i.e., a liquid encapsulant material or clearcoat). In this regard, the term “cured,” as used herein, refers to the condition of a liquid coating composition in which a film or layer formed from the liquid coating composition is at least set-to-touch. As used herein, the terms “cure” and “curing” refer to the progression of a liquid coating composition from the liquid state to a cured state and encompass physical drying of coating compositions through solvent or carrier evaporation (e.g., thermoplastic coating compositions) and/or chemical crosslinking of components in the coating compositions (e.g., thermosetting coating compositions).

The back coat can provide an overcoat or protective and/or durable coating. In various aspects the back coat comprises the outermost backing layer of a photovoltaic module in accordance with various aspects described in this specification. The back coat can comprise multiple coats, wherein any coat or coats can individually comprise the same or different coating compositions. In various aspects, a photovoltaic module can comprise a topcoat as the outermost backing layer of the photovoltaic module, unlike some photovoltaic module designs that rely on a film that can be laminated and/or a back sheet (such as glass, metal, etc.).

In various aspects, the photovoltaic modules 100 and 200 can comprise an electrocoat as described in co-pending U.S. patent application “Electrocoated Photovoltaic Modules and Methods of Making Same” to Shao et al. (Attorney Docket No. 9076A1), which is filed concurrently herewith and is incorporated by reference into this specification.

In various aspects, the photovoltaic modules, and all aspects thereof, as described above, can further include a primer coat. For example, the back coat 110 or 206 of the photovoltaic module 100 or 200 can further comprise a primer coat positioned in between the back coat 110 or 206 and the photovoltaic cells 102 or 204, or between the back coat 110 or 206 and a back side of the encapsulant layer (not shown). As used herein, the term “primer coat” or “primer coating composition” refers to coats or coating compositions forming an undercoating deposited onto a substrate over which a topcoat can be deposited. The primer coat can provide for anti-corrosion protection. The primer coat can comprise any suitable coating compositions such as, for example, DOW CORNING® 1200 OS Primer (a primer for silicone adhesives/sealants) commercially available from Dow Corning, Midland, Mich., USA, PPG DP40 refinish primer, PPG aerospace CA7502 primer, (both commercially available from PPG Industries, Inc., Pittsburgh, Pa., USA), other epoxy/amine primers, or combinations thereof.

The back coat 110 or 206 alone or in combination with a primer coating and/or other coatings can comprise a primer-topcoat system (not shown) that can be applied to coat the photovoltaic module 100 or 200 or the back side of the photovoltaic cells 102 or 204 (as well as the electrical interconnections 108 connected to the photovoltaic cells 102 of the photovoltaic module 100 in bulk photovoltaic modules (shown in FIG. 1)).

In various aspects, the primer-topcoat system comprises one, two, or more coats, wherein any coat or coats can individually comprise the same or a different coating composition. In various aspects, the coatings used to produce the coats (e.g., primer coat, tie coat, topcoat, monocoat, and the like) comprising a protective coating system for a photovoltaic module can comprise inorganic particles in the coating composition and the resultant cured coating film. As used herein, tie coat refers to an intermediate coating intended to facilitate or enhance adhesion between an underlying coating (such as a primer coat or an electrocoat) and an overlying back coat.

In some aspects, the coatings (e.g., back coats 110 and 206 and/or any underlying primer or tie coats), can comprise particulate mineral materials, such as, for example, mica, which can be added to the coating compositions used to produce a protective coating system for photovoltaic modules 100 or 200. In various aspects, the inorganic particles can comprise aluminum, silica, clays, pigments, and/or glass flake, or combinations thereof. Inorganic particles can be added to the primer coat, tie coat, back coat, topcoat and/or monocoat applied on to the photovoltaic cells 102 or 204 and the electrical interconnections 108 to coat and/or encapsulate these components.

Protective coating systems comprising inorganic particles in the cured coats can exhibit improved barrier properties such as, for example, lower moisture vapor transmission rates and/or lower permeance values. Inorganic particles such as, for example, mica and other mineral particulates, can improve the moisture barrier properties of polymeric films and coats by increasing the tortuosity of transport paths for water molecules contacting the films or coats. These improvements can be attributed to the relatively flat platelet-like structure of various inorganic particles. In various aspects, inorganic particles can comprise a platelet shape. In various aspects, inorganic particles can comprise a platelet shape and include an aspect ratio, defined as the ratio of the average width dimension of the particles to the average thickness dimension of the particles, ranging from 5 to 100 microns, or any sub-range subsumed therein. In various aspects the inorganic particles have an average particle size ranging from 10 to 40 microns, or any sub-range subsumed therein.

Inorganic particles, such as, for example, mica, can be dispersed in the cured coating layer. In various aspects the inorganic particles are mechanically stirred and/or mixed into the coatings, or added following creation of a slurry. In various aspects, a surfactant can be used. In various aspects inorganic particles can be mixed until fully distributed in the cured coating layer without settling.

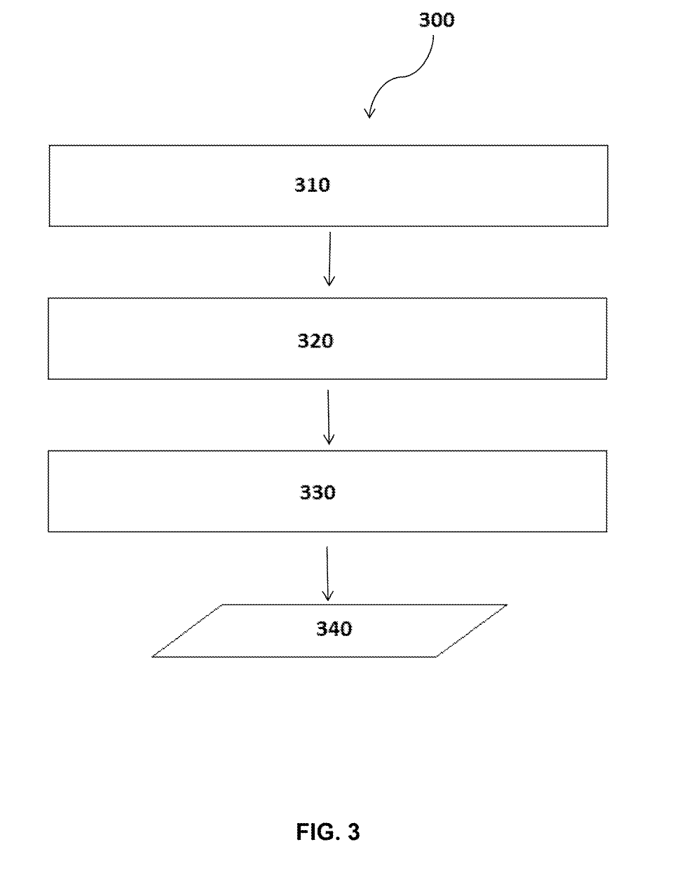

FIG. 3 schematically illustrates a method 300 of production of a photovoltaic module. The method 300 for preparing a photovoltaic module comprises positioning (step 310) the photovoltaic cell adjacent to a front transparency, depositing (step 320) a back coat onto a back side of the photovoltaic cell opposite the front transparency, and curing (step 330) the deposited back coat to form a photovoltaic module 340 (step 340). The back coat applied by the method 300 can comprise a polyurea formed from a coating composition comprising a polyisocyanate, a polyamine, a diamine chain extender, and an amine-functional and/or hydroxy-functional siloxane. In various aspects the method 300 can further comprise positioning an encapsulant layer adjacent to the front transparency, wherein the photovoltaic cell comprises a crystalline silicone photovoltaic cell that can be positioned on the encapsulant layer.

It is understood that the terms “positioning,” “depositing,” and their grammatical variants, as used herein, refer to placing a referenced component in a spatial relationship with another component, wherein the components may be either placed in direct physical contact or indirectly placed beside each other with an intervening component or space. Accordingly, and by way of example, where a first component is said to be positioned or deposited on, onto, or over a second component, it is understood that the first component can be, but is not necessarily, in direct physical contact with the second component. The terms “positioning” and “depositing can be used interchangeably, but in various aspects “positioning” and its grammatical variants can refer to placing a preexisting component, such as, for example, placing a photovoltaic cell or a pre-formed sheet of material, and the term “depositing” and its grammatical variants can refer to forming a component in situ, such as, for example, applying a liquid coating layer or otherwise forming a component using a chemical or physical deposition technique.

As used herein, the term “adjacent” describes the relative positioning of layers, coats, films, sheets, photovoltaic cells, and other components comprising a photovoltaic module, wherein the components can be either in direct physical contact or indirectly positioned beside another component with an intervening component or space. Accordingly, and by way of example, where a first component is said to be positioned adjacent to a second component, it is understood that the first component can be, but is not necessarily, in direct physical contact with the second component.

It is contemplated that one coat or component can be either directly positioned or indirectly positioned beside another adjacent component or coat. In various aspects where one component or coat is indirectly positioned beside another component or coat, it is contemplated that additional intervening layers, coats, photovoltaic cells, and the like can be positioned in between adjacent components. Accordingly, and by way of example, where a first coat can be said to be positioned adjacent to a second coat, it is contemplated that the first coat can be, but is not necessarily, directly beside and adhered to the second coat.

Similar elements of the photovoltaic module 340 comprise substantially similar materials and perform substantially similar functions as those corresponding elements described above in connection to the photovoltaic modules 100 and 200 shown respectively in FIGS. 1 and 2. For example, the photovoltaic cell, the front transparency, and the back coat of the photovoltaic module 340 (see step 310) comprise the same materials and perform the same functions, respectively, as the photovoltaic cell 102, the front transparency 106, and the back coat 110 of the photovoltaic module 100 of FIG. 1.

The method 300 (see FIG. 3) can further comprise positioning an encapsulant layer adjacent to the front transparency. Similar to the encapsulant layer 106 of the photovoltaic module 100, the encapsulant layer of the photovoltaic module 340 can comprise ethylene vinyl acetate or a cured clear fluid encapsulant. In various aspects, the photovoltaic cell of method 300 comprises a crystalline silicon photovoltaic cell that can be positioned on the encapsulant layer.

In various aspects, depositing the back coat (see step 320) comprises spraying the back coat onto the back side of the photovoltaic cell opposite the front transparency. As described above in connection with the back coats 110 and 206, the back coat of photovoltaic module 340 can be deposited onto all or a portion of the photovoltaic cell to form a coat or layer thereon (e.g., topcoat, primer coat, tie coat, clearcoat, or the like) using any suitable coating application technique. For example, the coatings of the present disclosure can be applied by spraying, dipping, rolling, brushing, roller coating, curtain coating, flow coating, slot die coating, and the like.

Accordingly, the present disclosure provides various aspects of the photovoltaic module and related methods. For example, in a first aspect, Aspect 1, the present disclosure provides a photovoltaic module comprising a front transparency, at least one photovoltaic cell, and a back coat, wherein the back coat comprises a cured polyurea resin formed from a coating composition.

In another aspect, Aspect 2, the present disclosure provides a photovoltaic module as provided in Aspect 1, wherein the coating composition comprises a polyisocyanate, a polyamine, a diamine chain extender, and an amine-functional and/or hydroxy-functional siloxane.

In another aspect, Aspect 3, the present disclosure provides a photovoltaic module as provided in either Aspects 1 or 2, wherein the coating composition comprises a polyamine that comprises a polyaspartic ester and/or a cyclo-aliphatic polyaspartic ester.

In another aspect, Aspect 4, the present disclosure provides a photovoltaic module as provided in any of Aspects 1-3, wherein the coating composition comprises a diamine chain extender that comprises an aliphatic cyclic secondary amine.

In another aspect, Aspect 5, the present disclosure provides a photovoltaic module as provided in any of Aspects 1-4, wherein the coating composition comprises an amine-functional siloxane.

In another aspect, Aspect 6, the present disclosure provides a photovoltaic module as provided in any of Aspects 1-5, wherein the back coat further comprises a polyether-polyamine.

In another aspect, Aspect 7, the present disclosure provides a photovoltaic module as provided in any of Aspects 1-6, wherein the back coat further comprises a polyether-polyamine and the polyether-polyamine comprises a polyether-triamine.

In another aspect, Aspect 8, the present disclosure provides a photovoltaic module as provided in any of Aspects 1-7, wherein the at least one photovoltaic cell comprises at least one bulk photovoltaic cell comprising a crystalline silicon wafer.

In another aspect, Aspect 9, the present disclosure provides a photovoltaic module as provided in any of Aspects 1-8, wherein the at least one photovoltaic cell comprises at least one thin-film photovoltaic cell comprising a plurality of deposited photovoltaic layers.

In another aspect, Aspect 10, the present disclosure provides a photovoltaic module as provided in any of Aspects 1-9, wherein the back coat comprises a spray applied and cured layer of polyurea resin formed from the coating composition.

In another aspect, Aspect 11, the present disclosure provides a photovoltaic module as provided in any of Aspects 1-10, wherein the back coat exhibits a Young's modulus in the range of 10 MPa to 900 MPa.

In another aspect, Aspect 12, the present disclosure provides a photovoltaic module as provided in any of Aspects 1-11, wherein the back coat exhibits a moisture vapor transmission rate permeance in the range of 1 to 1000 g*mil/m²*day.

In another aspect, Aspect 13, the present disclosure provides a photovoltaic module as provided in any of Aspects 1-12, wherein the back coat exhibits a dry insulation resistance greater than 400 MΩ.

In another aspect, Aspect 14, the present disclosure provides a photovoltaic module as provided in any of Aspects 1-13, further comprising an encapsulant layer adjacent to the front transparency.

In another aspect, Aspect 15, the present disclosure provides a photovoltaic module as provided in any of Aspects 1-14, further comprising an encapsulant layer and wherein the encapsulant layer comprises a cured clear fluid encapsulant and/or ethylene vinyl acetate.

In another aspect, Aspect 16, the present disclosure provides a photovoltaic module comprising a front transparency, at least one photovoltaic cell, and a back coat wherein the back coat comprises a cured polyurea resin formed from a coating composition comprising a polyisocyanate, a polyamine having the structure:

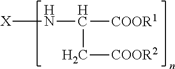

wherein:
n is an integer of 2 to 4
X represents an aliphatic residue; and
R¹ and R² represent organic groups that are inert to isocyanate groups;

a diamine chain extender having the structure:

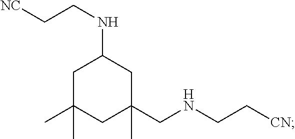 [SMILES: CC1(C)CC(NCCC#N)CC(C)(CNCCC#N)C1]

an amine-functional and/or hydroxy-functional siloxane.

In another aspect, Aspect 17, the present disclosure provides a photovoltaic module as provided in Aspect 16, wherein the polyamine comprises a polyamine having the structure:

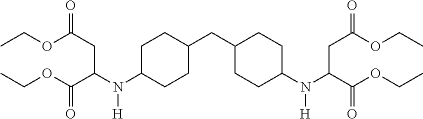 [SMILES: CCOC(=O)CC(NC1CCC(CC2CCC(NC(CC(=O)OCC)C(=O)OCC)CC2)CC1)C(=O)OCC]

In another aspect, Aspect 18, the present disclosure provides a method for preparing any of the photovoltaic modules of Aspects 1-17, comprising: positioning at least one photovoltaic cell adjacent to a front transparency; depositing a back coat onto a back side of the photovoltaic cell opposite the front transparency; and curing the deposited back coat; wherein the back coat comprises a polyurea formed from a coating composition.

Various aspects are described and illustrated in this specification to provide an overall understanding of the structure, function, properties, and use of the disclosed modules and processes. It is understood that the various aspects described and illustrated in this specification are non-limiting and non-exhaustive. Thus, the present disclosure is not limited by the description of the various aspects disclosed in this specification. The features and characteristics described in connection with various aspects can be combined with the features and characteristics of other aspects. Such modifications and variations are intended to be included within the scope of this specification. As such, the claims can be amended to recite any features or characteristics expressly or inherently described in, or otherwise expressly or inherently supported by, this specification. Further, Applicants reserve the right to amend the claims to affirmatively disclaim features or characteristics that may be present in the prior art. Therefore, any such amendments comply with written description support requirements. The various aspects disclosed and described in this specification can comprise, consist of, or consist essentially of the features and characteristics as variously described herein.

In this specification, other than where otherwise indicated, all numerical parameters are to be understood as being prefaced and modified in all instances by the term “about”, in which the numerical parameters possess the inherent variability characteristic of the underlying measurement techniques used to determine the numerical value of the parameter. At the very least, and not as an attempt to limit the application of the doctrine of equivalents to the scope of the claims, each numerical parameter described in this specification should at least be construed in light of the number of reported significant digits and by applying ordinary rounding techniques.

Also, any numerical range recited in this specification is intended to include all sub-ranges of the same numerical precision subsumed within the recited range. For example, a range of “1.0 to 10.0” is intended to include all sub-ranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited in this specification is intended to include all lower numerical limitations subsumed therein and any minimum numerical limitation recited in this specification is intended to include all higher numerical limitations subsumed therein. Accordingly, Applicants reserve the right to amend this specification, including the claims, to expressly recite any sub-range subsumed within the ranges expressly recited herein. All such ranges are intended to be inherently described in this specification such that amending to expressly recite any such sub-ranges would comply with written description support requirements.

The grammatical articles “one”, “a”, “an”, and “the”, as used in this specification, are intended to include “at least one” or “one or more”, unless otherwise indicated. Thus, the articles are used in this specification to refer to one or more than one (i.e., to “at least one”) of the grammatical objects of the article. By way of example, “a photovoltaic cell” means one or more photovoltaic cells, and thus, possibly, more than one photovoltaic cell is contemplated and can be employed or used in an implementation of the described aspects. Further, the use of a singular noun includes the plural, and the use of a plural noun includes the singular, unless the context of the usage requires otherwise.

Any patent, publication, or other disclosure material identified herein is incorporated by reference into this specification in its entirety unless otherwise indicated, but only to the extent that the incorporated material does not conflict with existing definitions, statements, or other disclosure material expressly set forth in this specification. As such, and to the extent necessary, the express disclosure as set forth in this specification supersedes any conflicting material incorporated by reference herein. Any material, or portion thereof, that is said to be incorporated by reference into this specification, but which conflicts with existing definitions, statements, or other disclosure material set forth herein, is only incorporated to the extent that no conflict arises between that incorporated material and the existing disclosure material. Applicant(s) reserve the right to amend this specification to expressly recite any subject matter, or portion thereof, incorporated by reference herein.

The non-limiting and non-exhaustive examples that follow are intended to further describe various aspects without restricting the scope of the aspects described in this specification.

### EXAMPLES

### Example-1

Bulk crystalline silicon photovoltaic modules comprising a protective coating system comprising a cured liquid back side encapsulant and a cured polyurea back coat were evaluated in accordance with the International Electrotechnical Commission (IEC), International Standard, Second Edition (2005-04), “Crystalline silicon terrestrial photovoltaic (PV) modules—Design qualification and type approval” (IEC 61215:2005). All tested photovoltaic modules were obtained from SPI Supplies, Structure Probe, Inc. of West Chester, Pa. and comprised a single crystalline silicon photovoltaic cell adhered to a glass front transparency with EVA. The test modules were obtained in an incomplete form lacking a back side encapsulant and a backsheet.

A liquid thermosetting polyurethane coating was spray coated onto the back sides of the test modules, covering the photovoltaic cells, and cured to form a back side encapsulant layer. A thermosetting polyurea coating was spray coated onto the cured polyurethane encapsulant layer and cured to form a back coat. The polyurea back coat formulations are provided in Table 1 (values in weight percentages unless otherwise indicated).

TABLE 1

| Component | Formulation A | Formulation B |
|---|---|---|
| ^{1 L JEFFAMINE T5000} | — | 15.5 |
| ²DOW CORNING 3055 | 11.3 | 10.1 |
| ³DESMOPHEN NH 1220 | — | — |
| ⁴DESMOPHEN NH 1420 | 38.5 | 11.6 |
| ⁵HXA CE 425 | 38.5 | 27.7 |
| ⁶JEFFAMINE D2000 | — | 11.6 |
| ⁷JEFFLINK 754 | — | 15.5 |
| ⁸BYK-9077 | 0.6 | 0.4 |
| ⁹TINUVIN 292 | 2.0 | 1.5 |
| ¹⁰BENTONE 34 | 1.5 | 1.2 |
| ¹¹AEROSIL 200 | 1.5 | 1.2 |
| TiO₂ white pigment | 6.0 | 3.9 |
| ¹²Desmodur XP 2580 | NCO/active hydrogen | NCO/active |
| | ratio: 1.054 | hydrogen |
| | | ratio: 1.217 |

¹JEFFAMINE T15000 is a trifunctional primary polyoxypropylenediamine of approximately 5000 molecular weight available from Huntsman Corporation, The Woodlands, TX, USA.
²DOW CORNING 3055 is an amine-functional polysiloxane available from Dow Corning Corporation, Midland, MI, USA.
³DESMOPHEN NH 1220 is a polyaspartic ester available from Bayer Material Science LLC, Pittsburgh, PA, USA.
⁴DESMOPHEN NH 1420 is a polyaspartic ester available from Bayer Material Science LLC, Pittsburgh, PA, USA.
⁵HXA CE 425 is an aliphatic diamine chain extender available from The Hanson Group, LLC, Alpharetta, GA, USA.
⁶JEFFAMINE D2000 is a difunctional primary polyoxypropylenediamine of approximately 5000 molecular weight available from Huntsman Corporation, The Woodlands, TX, USA.
⁷JEFFLINK 754 is a cycloaliphatic isophorone-based secondary diamine available from Huntsman Corporation, The Woodlands, TX, USA.
⁸BYK-9077 is a wetting agent/dispersant available from Altanta AG, Wesel, Germany.
⁹TINUVIN 292 is a hindered amine UV stabilizer available from BASF, Ludwigshafen, Germany.
¹⁰BENTONE 34 is an organic derivative of bentonite clay theological additive available from Elementis Specialties, Inc., Highstown, NJ, USA.
¹¹AEROSIL 200 is a hydrophilic fumed silica available from Evonik Industries AG, Essen, Germany.
¹²Desmodur XP 2580 is an aliphatic polyisocyanate based on hexamethylene diisocyanate available from Bayer Material Science LLC, Pittsburgh, PA, USA.

Four polyurethane and polyurea spray coated test modules were subjected to damp heat testing under IEC 61215:2005 Standard Test 10.13, conducted in accordance with IEC 60068-2-78 (85±2° C., 85±3% relative humidity). The damp heat test modules were tested for dry insulation properties (the electrical resistance of the back coating) in accordance with IEC 61215:2005 Standard Test 10.13 after 500, 1500, 2000, and 2500 hours of damp beat (DH) exposure. The dry insulation resistance must be greater than 400 MΩ to pass the IEC 61215:2005 Standard Test 10.13. The results of the damp heat/dry insulation testing are provided in Table 2.

TABLE 2

| | | | Dry | Dry | Dry | Dry |
|---|---|---|---|---|---|---|
| | | | Insulation | Insulation | Insulation | Insulation |
| | | Dry Film | Value | Value | Value | Value |
| Test | Back | Thickness of | (MΩ) | (MΩ) | (MΩ) | (MΩ) |
| Module | Coat | Back Coat | 500 hr. | 1500 hr. | 2000 hr. | 2500 hr. |
| ID | Formulation | (mils) | DH | DH | DH | DH |
| 1 | A | 22.1 | >2000 | >2000 | >2000 | >2000 |
| 2 | A | 17.6 | >2000 | >2000 | >2000 | >2000 |
| 3 | B | 20.3 | >2000 | >2000 | >2000 | >2000 |
| 4 | B | 28.2 | >2000 | >2000 | >2000 | >2000 |

### Example-2

Bulk crystalline silicon photovoltaic modules comprising a protective coating system comprising a cured liquid back side encapsulant and a cured polyurea back coat were evaluated in accordance with the International Electrotechnical Commission (IEC), International Standard, Second Edition (2005-04), “Crystalline silicon terrestrial photovoltaic (PV) modules—Design qualification and type approval” (IEC 61215:2005). All tested photovoltaic modules were obtained from SPI Supplies, Structure Probe, Inc. of West Chester, Pa. and comprised a single crystalline silicon photovoltaic cell adhered to a glass front transparency with EVA. The test modules were obtained in an incomplete form lacking a back side encapsulant and a backsheet.

A liquid thermosetting polyurethane coating % as spray coated onto the back sides of the test modules, covering the photovoltaic cells, and cured to form a back side encapsulant layer. A thermosetting polyurea coating was spray coated onto the cured polyurethane encapsulant layer and cured to form a back coat. The polyurea back coat formulation is provided in Table 3 (values in weight percentages unless otherwise indicated).

TABLE 3

| Component | Back Coat Formulation |
|---|---|
| JEFFAMINE T5000 | 20.0 |
| DESMOPHEN NH 1420 | 23.3 |
| HXA CE 425 | 41.9 |
| ¹TEGO PROTECT 5000 | 4.0 |
| BYK-9077 | 0.5 |
| TINUVIN 292 | 2.0 |
| BENTONE 34 | 1.5 |
| AEROSIL 200 | 1.0 |
| TiO₂ white pigment | 5.05 |
| Desmodur XP 2580 | NCO/active hydrogen ratio: |
| | 1.266 |

¹Tego Protect 5000 is a hydroxy-functional dimethyl siloxane available from Evonik Industries AG, Essen, Germany.

A polyurethane and polyurea spray coated test modules were subjected to damp heat testing under IEC 61215:2005 Standard Test 10.13, conducted in accordance with IEC 60068-2-78 (85±2° C., 85±3% relative humidity). The damp heat test modules were tested for power retention also in accordance with IEC 61215:2005 Standard Test 10.13, conducted in accordance with IEC 60068-2-78 (85±2° C., 85±3% relative humidity) for a period of 1000 hours of damp heat (DH) exposure. The test modules exhibited 95-97% power retention after 1000 hours of damp heat testing.

This specification has been written with reference to various aspects. However, it will be recognized by persons having ordinary skill in the art that various substitutions, modifications, or combinations of any of the disclosed aspects (or portions thereof) can be made within the scope of this specification. Thus, it is contemplated and understood that this specification supports additional aspects not expressly set forth herein. Such aspects can be obtained, for example, by combining, modifying, or reorganizing any of the disclosed steps, step sequences, components, elements, features, aspects, characteristics, limitations, and the like, of the various aspects described in this specification. In this manner, Applicant(s) reserve the right to amend the claims during prosecution to add features as variously described in this specification, and such amendments comply with written description support requirements.

What is claimed is:

1. A photovoltaic module comprising:
a front transparency;
at least one photovoltaic cell; and
a back coat;
wherein the back coat comprises a cured polyurea resin formed from a coating composition.

2. The photovoltaic module of claim 1, wherein the coating composition comprises:
a polyisocyanate;
a polyamine;
a diamine chain extender, and
an amine-functional and/or hydroxy-functional siloxane.

3. The photovoltaic module of claim 2, wherein the polyamine comprises a polyaspartic ester.

4. The photovoltaic module of claim 2, wherein the polyamine comprises a cyclo-aliphatic polyaspartic ester.

5. The photovoltaic module of claim 2, wherein the diamine chain extender comprises an aliphatic cyclic secondary amine.

6. The photovoltaic module of claim 2, wherein the siloxane comprises an amine-functional siloxane.

7. The photovoltaic module of claim 1, wherein the back coat further comprises a polyether-polyamine.

8. The photovoltaic module of claim 7, wherein the polyether-polyamine comprises a polyether-triamine.

9. The photovoltaic module of claim 1, wherein the at least one photovoltaic cell comprises at least one bulk photovoltaic cell comprising a crystalline silicon wafer.

10. The photovoltaic module of claim 1, wherein the at least one photovoltaic cell comprises at least one thin-film photovoltaic cell comprising a plurality of deposited photovoltaic layers.

11. The photovoltaic module of claim 1, wherein the back coat comprises a spray applied and cured layer of polyurea resin formed from the coating composition.

12. The photovoltaic module of claim 1, wherein the back coat exhibits a Young's modulus in the range of 10 MPa to 900 MPa.

13. The photovoltaic module of claim 1, wherein the back coat exhibits a moisture vapor transmission rate permeance in the range of 1 to 1000 g*mil/m²*day.

14. The photovoltaic module of claim 1, wherein the back coat exhibits a dry insulation resistance greater than 400 MΩ.

15. The photovoltaic module of claim 1, further comprising an encapsulant layer adjacent to the front transparency.

16. The photovoltaic module of claim 15, wherein the encapsulant layer comprises a cured clear fluid encapsulant.

17. The photovoltaic module of claim 15, wherein the encapsulant layer comprises ethylene vinyl acetate.

18. A photovoltaic module comprising:
a front transparency;
at least one photovoltaic cell; and
a back coat;
wherein the back coat comprises a cured polyurea resin formed from a coating composition comprising:
a polyisocyanate;
a polyamine having the structure: 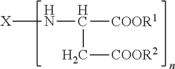
wherein:
n is an integer of 2 to 4
X represents an aliphatic residue; and
R¹ and R² represent organic groups that are inert to isocyanate groups;
a diamine chain extender having the structure: 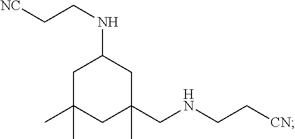 [SMILES: CC1(C)CC(NCCC#N)CC(C)(CNCCC#N)C1]
and
an amine-functional and/or hydroxy-functional siloxane.

19. The photovoltaic module of claim 18, wherein the polyamine comprises a polyamine having the structure:

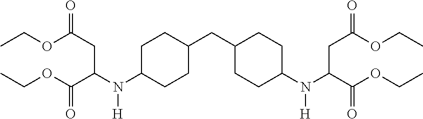 [SMILES: CCOC(=O)CC(NC1CCC(CC2CCC(NC(CC(=O)OCC)C(=O)OCC)CC2)CC1)C(=O)OCC]

20. A method for preparing a photovoltaic module comprising:
positioning at least one photovoltaic cell adjacent to a front transparency;
depositing a back coat onto a back side of the photovoltaic cell opposite the front transparency; and
curing the deposited back coat;
wherein the back coat comprises a polyurea formed from a coating composition.
